(19) United States
(12) Patent Application Publication
(10) Pub. No.: US 2009/0008729 A1
(43) Pub. Date: Jan. 8, 2009

(54) IMAGE SENSOR PACKAGE UTILIZING A REMOVABLE PROTECTION FILM AND METHOD OF MAKING THE SAME

(75) Inventors: Wen-Kun Yang, Hsin-Chu City (TW); Jui-Hsien Chang, Jhudong Township (TW); Chi-Chen Lee, Taipei City (TW); Wen-Ping Yang, Hsinchu City (TW)

Correspondence Address: KUSNER & JAFFE;HIGHLAND PLACE SUITE 310, 6151 WILSON MILLS ROAD, HIGHLAND HEIGHTS, OH, 44143, US

(73) Assignee: Advanced Chip Engineering Technology Inc.

(21) Appl. No.: 11/772,861

(22) Filed: Jul. 3, 2007

(51) Int. Cl. H01L 31/0232; H01L 21/00

(52) U.S. Cl. 257/432; 250/239; 438/116; 257/E31.127

(57) ABSTRACT

The present invention discloses a structure of image sensor package utilizing a removable protection film. The structure comprises a substrate with a die receiving cavity and inter-connecting through holes. Terminal pads are formed under the inter-connecting through holes and metal pads are formed on an upper surface of the substrate. A die is disposed within the die receiving cavity by an adhesion material. Bonding pads are formed on the upper edge of the die. Bonding wires are coupled to the metal pads and the bonding pads. A protection layer is formed on the micro lens area to protect the micro lens from particle contamination. A removable protection film is formed over the protection layer to protect the micro lens from water, oil, dust or temporary impact during the packaging and assembling process.

### FIELD OF THE INVENTION

The present invention relates to a structure of an image sensor package, and more particularly, to a structure of an image sensor utilizing a removable protection film.

### BACKGROUND OF THE INVENTION

In the field of semiconductor devices, the device density is increased and the device dimension is reduced continuously. The demand for the packaging or interconnecting techniques in such high density devices is also increased to fit the situation mentioned above. Conventionally, in the flip-chip attachment method, an array of solder bumps is formed on the surface of the die. The formation of the solder bumps may be carried out by using a solder composite material through a solder mask for producing a desired pattern of solder bumps. The function of chip package includes power distribution, signal distribution, heat dissipation, protection and support . . . and so on. As semiconductor becomes more complicated, the traditional package technique, for example lead frame package, flex package, rigid package technique, can not meet the demand of producing smaller chip with high density elements on the chip.

Complementary metal-oxide semiconductor (CMOS) devices are increasingly in demand for use with electronic devices such as digital cameras. Conventionally, these sensors have been packaged for use by mounting them to a substrate and enclosing them within a housing assembly. The housing assembly incorporates a transparent lid to allow light or other forms of radiation to be received by the sensor. The lid may be a flat window or shaped as a lens to provide optical properties. Due to the conventional structure involved, this packaging technique may be expensive and difficult to manufacture. U.S. Pat. No. 6,809,008 assigned to Motorola, Inc. (Schaumburg, Ill.) disclosed an exemplary system and method for providing an integrated photosensing element suitably adapted for use in CMOS imaging applications.

Furthermore, because conventional package technologies have to divide a dice on a wafer into respective dies and then package the die respectively, therefore, these techniques are time consuming for manufacturing process. Since the chip package technique is highly influenced by the development of integrated circuits, therefore, as the size of electronics has become demanding, so does the package technique. For the reasons mentioned above, the trend of package technique is toward ball grid array (BGA), flip chip (FC-BGA), chip scale package (CSP), Wafer level package (WLP) today. “Wafer level package” is to be understood as meaning that the entire packaging and all the interconnections on the wafer as well as other processing steps are carried out before the singulation (dicing) into chips (dies). Generally, after completion of all assembling processes or packaging processes, individual semiconductor packages are separated from a wafer having a plurality of semiconductor dies. The wafer level package has extremely small dimensions combined with extremely good electrical properties.

WLP technique is an advanced packaging technology, by which the die are manufactured and tested on the wafer, and then singulated by dicing for assembly in a surface-mount line. Because the wafer level package technique utilizes the whole wafer as one object, not utilizing a single chip or die, therefore, before performing a scribing process, packaging and testing has been accomplished; furthermore, WLP is such an advanced technique so that the process of wire bonding, die mount and under-fill can be omitted. By utilizing WLP technique, the cost and manufacturing time can be reduced, and the resulting structure of WLP can be equal to the die; therefore, this technique can meet the demands of miniaturization of electronic devices.

Though the advantages of WLP technique mentioned above, some issues still exist influencing the acceptance of WLP technique. For example, although utilizing WLP technique can reduce the CTE mismatch between IC and the interconnecting substrate, as the size of the device minimizes, the CTE difference between the materials of a structure of WLP becomes another critical factor to mechanical instability of the structure. Furthermore, in this wafer-level chip-scale package, a plurality of bond pads formed on the semiconductor die is redistributed through conventional redistribution processes involving a redistribution layer (RDL) into a plurality of metal pads in an area array type. Solder balls are directly fused on the metal pads, which are formed in the area array type by means of the redistribution process. Typically, all of the stacked redistribution layers are formed over the built-up layer over the die. Therefore, the thickness of the package is increased. This may conflict with the demand of reducing the size of a chip.

Regarding that the conventional methods of packaging image sensor device either using the Chip On Board (COB) or using the Leadless Carrier Cavity (LCC) with wire bonding structure suffered the yield problem during process, it was due to the particle contamination on the micro lens area which can not be removed after process.

Therefore, the present invention provides a solution to the aforementioned problem to protect the micro lens area from particle contamination and to reduce the thickness of the die package during the entire process.

### SUMMARY OF THE INVENTION

In accordance with the present invention, there is provided a structure of image sensor package comprising a substrate with a die receiving hole formed therein and inter-connecting through holes formed there through. Terminal pads are formed under the inter-connecting through holes and first pads are formed on an upper surface of the substrate. A die having a micro lens area is disposed within the die receiving hole by an adhesion material. Second pads (I/O pads) are formed on the upper edge of the die. Connecting structures formed on the die and the substrate for electrical communication are coupled to the first pads and the second pads. A protection layer is formed on the micro lens area to protect the micro lens from particle contamination. A removable protection film is formed over the protection layer to protect the micro lens from water, oil, dust, and temporary impact. The removable protection film is removed after the formation of the image sensor package and before mounting the lens holder on the top of micro lens area to form the image sensor module.

In accordance with another aspect of the present invention, there is provided a method for assembling image sensor package comprising coating a protection layer with water and oil repellency onto a silicon substrate with micro lens; coating a removable protection film onto the protection layer; opening non-micro lens areas of the substrate; mounting the image sensor package on a printed circuit board (PCB) by the surface mounting technology (SMT) process; and stripping away the removable protection film from the micro lens area. The step of opening non-micro lens areas of the substrate comprises exposure and developing processes to open the non-micro lens areas. Further, the method comprises forming redistribution lines (RDL) or wire bonding before coating a top protection layer and mounting a lens holder on the CMOS Image Sensor (CIS) package area to form a module.

One advantage of the present invention is the removable protection film coated on the micro lens after the wafer fabs out and/or after the protection layer with water and oil repellency is coated.

Another advantage of the present invention is the removable protection film which can be temporarily struck on the micro lens area during the packaging and assembling process.

A still further advantage of the present invention is the removable protection film which can prevent any particle contamination on the micro lens area during the packaging and assembling process.

Another advantage of the present invention is the removable protection film which can be stripped away from the micro lens area after the packaging and assembling process is completed and before a lens holder is put on the die package.

A still further advantage of the present invention is the removable protection film which promotes the easiness and the highest yield of the process.

A still further advantage of the present invention is that no clean process is needed by utilizing the removable protection film.

Another advantage of the present invention is the removable protection film which can be widely applied in many kinds of packaging and assembling processes such as COB, LCC, CSP, FO-WLP, etc.

These and other advantages will become apparent from the following description of preferred embodiments taken together with the accompanying drawings and the appended claims.

### BRIEF DESCRIPTION OF THE DRAWINGS

FIG. 1 is a cross-sectional view diagram of an image sensor package in accordance with one embodiment of the present invention.

FIG. 2 is a cross-sectional view diagram of an image sensor package in accordance with another embodiment of the present invention.

FIG. 3 is a cross-sectional view diagram of the image sensor package, illustrating that a protection film in the above embodiment may be stripped away from the micro lens area.

FIG. 4 is a cross-sectional view diagram of the silicon wafer of the image sensor in the exposure and developing processes in accordance with the present invention.

### DETAILED DESCRIPTION OF THE PREFERRED EMBODIMENT

The invention will now be described in greater detail with preferred embodiments of the invention and drawings attached. However, it should be appreciated that the preferred embodiments of the invention are described only for illustrating but not for limiting the claims of the invention. Besides the preferred embodiments mentioned herein, the present invention can be practiced in a wide range of other embodiments besides those explicitly described, and the scope of the present invention is expressly not limited expect as specified in the accompanying claims.

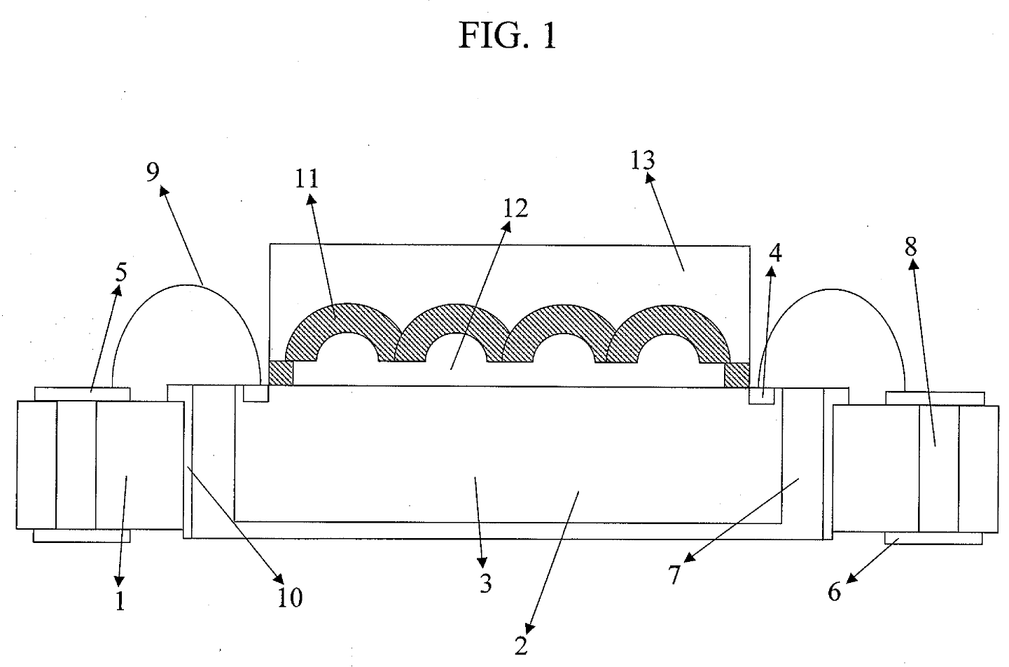

The present invention discloses a structure of an image sensor package utilizing a removable protection film. FIG. 1 illustrates a cross-sectional view of silicon wafer package of an image sensor in accordance with one embodiment of the present invention. As shown in FIG. 1, the structure of silicon wafer package includes a substrate 1 having a die receiving hole 2 formed therein to receive a die 3. The dimension of the width (size) of the die receiving hole 2 could be larger than the width (size) of the die 3 around 100 um each side. The gaps between the die 3 and the side and bottom walls of the hole 2 are filled with adhesion material 7 to fix the die 3 for protection for the backside of the die 3. The adhesion material 7 may include elastic material, photosensitive material, compound, epoxy resin, or silicone rubber. Bonding pads 4 (I/O pads) are formed near the edge of the upper side of the die 3. Metal pads 5 are formed on the upper surface of substrate 1 while terminal pads 6 are formed on the lower surface of the substrate 1. The bonding pads 4, the metal pads 5, and the terminal pads 6 are all conductive. A plurality of inter-connecting through holes 8 inside the substrate 1 pass through the substrate 1 from the upper surface to the lower surface of the substrate 1 and will be filled with a conductive material, such as metal, for electrical communication. The metal pads 5 and the terminal pads 6 are both connected to the inter-connecting through holes 8 with the conductive material. Bonding wires 9 are connected between the metal pads 5 and the bonding pads 4 and therefore keep electrically connected with the die 3 through the bonding pads 4, thereby forming inter-connecting contact with the terminal pads 6 through the metal pads 5.

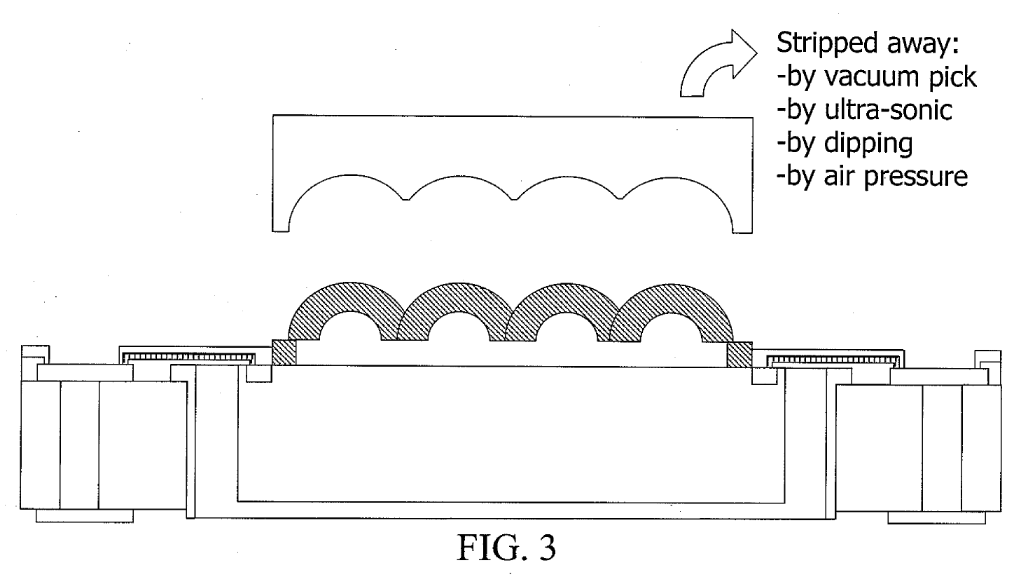

Furthermore, barrier layers 10 may be formed on the side wall of the substrate 1 for better adhesion with the adhesion material 7 as illustrated in FIG. 1. In one embodiment, the barrier layers 10 may be metal layers by using a metal plating method. It is appreciated that bonding pads 4 are formed on the die 3 by a metal plating method. A protection layer 11 is formed over the micro lens 12 which is arranged over the die 3. The protection layer 11 has water and oil repellent properties to protect the micro lens 12 from particle contamination and preferably has a thickness of 0.1-0.3 um and a reflectivity close to 1 (air reflectivity). The process can be executed by SOG (Spin on Glass) skill and can be processed either on silicon wafer form or panel wafer form, preferably in silicon wafer form to avoid the particle contamination during further process. The materials of the protection 11 layer may be SiO₂, Al₂O₃ or Fluoro-polymer. Furthermore, as illustrated in FIG. 1, a removable protection film 13 is coated over the protection layer 11 to protect the micro lens 12 from water, oil, dust or temporary impact during the packaging and assembly process in accordance with the present invention and can be stripped away by vacuum pick, ultrasonic, dipping, or air pressure as shown in FIG. 3. The removable protection film 13 adheres to the micro lens during all the process. The removable protection film 13 is preferably made of photosensitive materials and has a thickness of 5-12 um which is over the height of the micro lens. The area of the removable protection film 13 is slightly larger than the micro lens 12 area. It should be noted that the protection layer 11 is transparent to allow light passing through the layers 11 for exposing the micro lens 12.

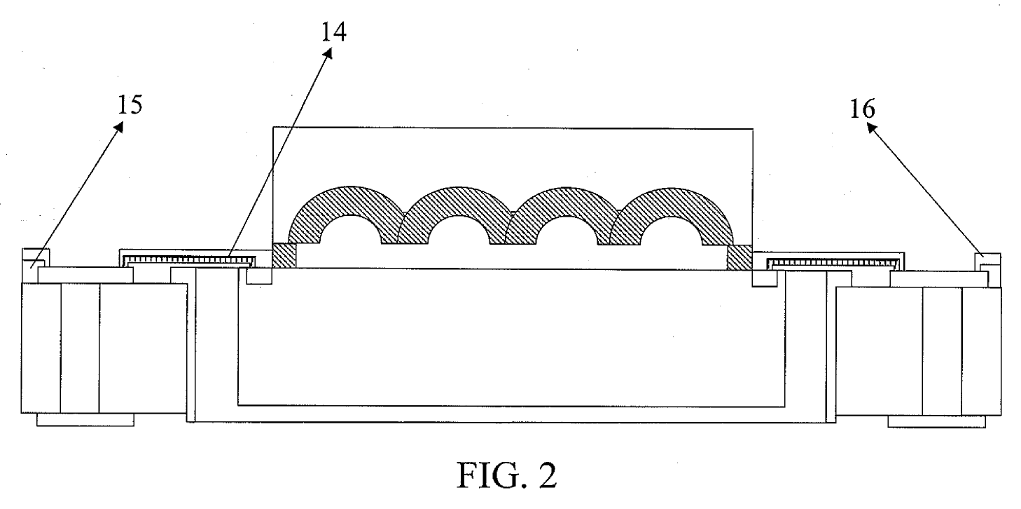

With reference to FIG. 2, in another embodiment, the aforementioned bonding wires may be replaced with redistribution lines (RDL) 14. A dielectric layer 15 is formed on the upper surface of the substrate and the upper edge of the die according to this embodiment. The redistribution lines 14, also referred to as metal trace 14, are formed on the dielectric layer 15 by removing predetermined portion of metal layer formed over the dielectric layer 15, wherein the RDLs 14 keep electrically connected with the die 3 through the bonding pads 4, thereby forming inter-connecting contact with the terminal pads 6 through the metal pads 5. A top dielectric layer 16 is formed over the RDLs 14 to protect the RDLs 14. In this embodiment, the dielectric layer 15 and the top dielectric layer 16 may be formed by coating or printing methods with photosensitive properties. Similarly, a protection film is formed over a protection layer on the micro lens to protect the micro lens from contamination. The other parts are similar to FIG. 1; therefore, the identical illustration and the reference numbers of the similar parts are omitted. The aforementioned structures constructs LGA type package (peripheral type).

Preferably, the material of the substrate 1 is an organic substrate such as FR5, FR4, BT (Bismaleimide triazine), PCB with defined opening or Alloy42 with pre-etching circuit. Preferably the organic substrate with high Glass transition temperature (Tg) is epoxy type FR5 or BT (Bismaleimide triazine) type substrate for better process performance. The Alloy42 is composed of 42% Ni and 58% Fe. Kovar can also be used and is composed of 29% Ni, 17% Co, and 54% Fe. The glass, ceramic, or silicon can be used as the substrate due to lower CTE.

In one embodiment of the present invention, the dielectric layer 15 and the top dielectric layer 16 is preferably an elastic dielectric material which is made by silicone dielectric based materials comprising siloxane polymers (SINR), Dow Coming WL5000 series, and composites thereof. In another embodiment, the dielectric layer 15 and the top dielectric layer 16 is made by a material comprising benzocyclobutene (BCB), epoxy, polyimides (PI) or resin. Preferably, it is a photosensitive layer for simple process.

In one embodiment of the present invention, the elastic dielectric layer is a kind of material with CTE larger than 100 (ppm/° C.), elongation rate about 40 percent (preferably 30 percent-50 percent), and the hardness of the material is between plastic and rubber. The thickness of the elastic dielectric layer 15 depends on the stress accumulated in the RDL/dielectric layer interface during temperature cycling test.

In one embodiment of the invention, the material of the RDLs 14 comprise Ti/Cu/Au alloy or Ti/Cu/Ni/Au alloy; the thickness of the RDLs 14 is between 2 um and 15 um. The Ti/Cu alloy is formed by sputtering technique also as seed metal layers, and the Cu/Au or Cu/Ni/Au alloy is formed by electro-plating; exploiting the electro-plating process to form the RDLs can make the RDLs thick enough to withstand CTE mismatching during temperature cycling. The bonding pads 4 can be Al or Cu or combination thereof. If the structure in FIG. 2 utilizes SINR as the elastic dielectric layer and Cu as the RDL metal, according to the stress analysis not shown here, the stress accumulated in the RDL/dielectric layer interface is reduced.

The substrate could be round type such as wafer type, wherein the diameter could be 200, 300 mm or higher. Otherwise, the substrate could be rectangular type such as panel form, and the dimension could be fit into the wire bonder machine. As shown in FIG. 1 and 2, the bonding wires 9 and the RDLs 14 fan out of the die 3 and communicate with the metal pads 5 and the bonding pads 4. It is different from the prior art technology which stacks layers over the die, thereby increasing the thickness of the package. On the contrary, the terminal pads 6 are located on the exterior surface that is opposite to the die pads side. The communication traces penetrate through the substrate 1 via the inter-connecting holes 8 and lead the signal to the terminal pads 8. Additionally, after the packaging and assembly process is completed, the removable protection film 13 could be stripped away before the dice are assembled with a lens holder. Therefore, the thickness shrinkage of the die package is apparently evident. The die package of the present invention will be thinner than the prior art and could be protected from particle contamination and temporary impact during the entire package and assembly process. Further, the substrate is pre-prepared and the die receiving hole 2 and the inter-connecting through holes 8 are predetermined before package. Hence, the throughput will be improved than ever.

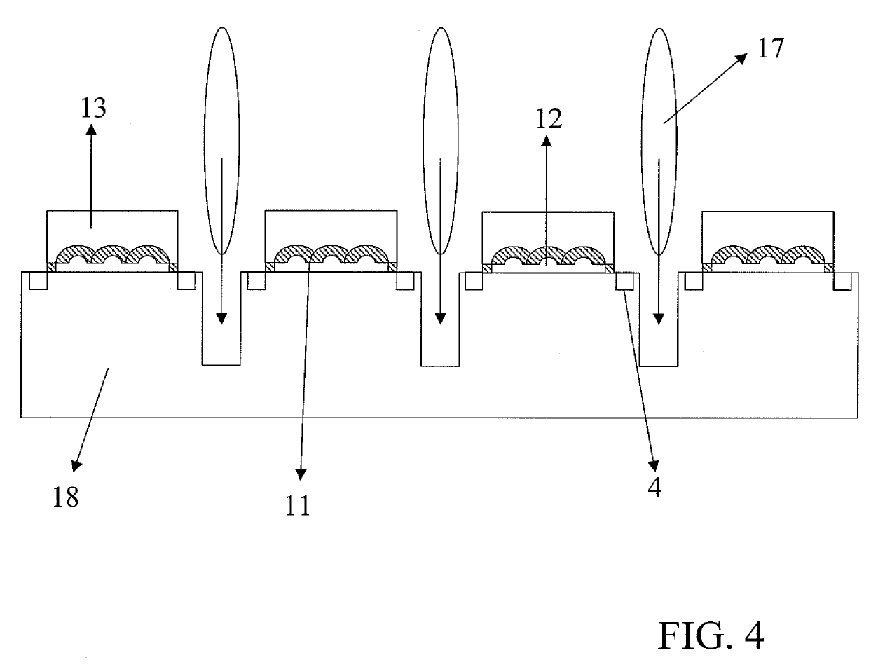

The process for the present invention includes coating a protection layer which has water and oil repellency onto the silicon wafer 18 with a thickness around 0.1 um to 0.3 um. Then, a removable protection film is coated onto the protection layer with a thickness around 5 um to 12 um, followed by using exposure and developing processes to open the non-micro lens areas with the removable protection film as illustrated in FIG. 4. In the exposure and developing processes, dicing saws 17 are utilized to cut the silicon wafer areas without micro lens as shown in FIG. 4. The removable protection film adheres to the micro lens during all the process. Further, the FO-WLP package is formed by using the redistribution lines (RDL) or wire bonding. The removable protection film 13 can protect the silicon wafer from water, oil, dust or other contamination during the process. Then, the image sensor package will be mounted on a printed circuit board (PCB) by the surface mounting technology (SMT) process and the removable protection film is stripped away from the micro lens area. Subsequently, the lens holder will be mounted on the CMOS Image Sensor (CIS) package area to form a module.

Although preferred embodiments of the present invention have been described, it will be understood by those skilled in the art that the present invention should not be limited to the described preferred embodiments. Rather, various changes and modifications can be made within the spirit and scope of the present invention, as defined by the following claims.

Having described the invention, the following is claimed:

1. A structure of image sensor package, comprising:
a die having micro lens area on the top surface;
a protection layer formed on the micro lens area; and
a removable protection film formed on said protection layer to protect the micro lens from water, oil, dust, and temporary impact during packaging and assembling processes, wherein said removable protection film is removed before mounting a lens holder with lens on the top of image sensor.

2. The structure of claim 1, further comprising:
a substrate with a die receiving hole formed therein, said die disposed within said die receiving hole by an adhesion material;
inter-connecting through holes formed there through, wherein terminal pads are formed under said inter-connecting through holes and first pads are formed on the upper surface of said substrate; and
a connecting wire coupled the I/O pads of chip to said first pads of said substrate.

3. The structure of claim 2, wherein said adhesion material includes compound, epoxy resin, or silicone rubber.

4. The structure of claim 2, wherein the material of said substrate includes FR4, FR5, BT, or PCB.

5. The structure of claim 2, wherein the material of said substrate includes alloy, metal, glass, silicon, or ceramic.

6. The structure of claim 2, wherein said connecting wire includes bonding wires or redistribution conductive lines (RDL).

7. The structure of claim 1, wherein the material of said protection layer includes SiO₂, Al₂O₃ or Fluoro-polymer.

8. The structure of claim 1, wherein said protection layer has water repellency and oil repellency properties.

9. The structure of claim 1, wherein the material of said removable protection film includes a photosensitive material.

10. The structure of claim 1, wherein the thickness of said removable protection film is over the height of the micro lens.

11. A method for assembling image sensor package, comprising:
coating a protection layer with water and oil repellency onto a die (silicon wafer) with micro lens;
coating a removable protection film onto said protection layer; and
opening non-micro lens area of said die (silicon wafer).

12. The method of claim 11, further comprising:
disposing said die into a substrate with a die receiving hole and adhering said die by an adhesion material; and
forming a connecting wire to couple the I/O pads of said die and first pads of said substrate.

13. The method of claim 12, further comprising:
mounting said image sensor package on a print circuit board (PCB) by the surface mounting technology (SMT) process;
stripping away said removable protection film from the micro lens area; and
mounting a lens holder with lens on said image sensor package to form a module.

14. The method of claim 12, wherein said connecting wire includes bonding wires or redistribution lines (RDL).

15. The method of claim 11, further comprising:
mounting said image sensor device on a print circuit board (PCB) by die attached process;
forming a connecting wire to couple the I/O pads of said die and first pads of said substrate;
stripping away said removable protection film from the micro lens area; and
mounting a lens holder with lens on said image sensor device to form a module.

16. The method of claim 15, wherein said connecting wire includes bonding wires or redistribution lines (RDL).

17. The method of claim 11, wherein the step of opening non-micro lens area of said silicon wafer comprising exposure and developing processes.

18. A structure of image sensor device, comprising:
a die having micro lens area on the top surface; and
a removable protection film formed on said micro lens area to protect the micro lens from water, oil, dust, and temporary impact during packaging and assembling processes, wherein said removable protection film is removed before mounting a lens holder with lens on the top of image sensor.
